(19) United States
(12) Patent Application Publication
(10) Pub. No.: US 2025/0212431 A1
(43) Pub. Date: Jun. 26, 2025

(54) SEMICONDUCTOR DEVICE FOR HIGH-VOLTAGE APPLICATION

(71) Applicant: TAIWAN SEMICONDUCTOR MANUFACTURING COMPANY LTD., HSINCHU (TW)

(72) Inventors: TUNG-YANG LIN, NEW TAIPEI CITY (TW); HUNG-CHIH TSAI, KAOHSIUNG CITY (TW); RUEY-HSIN LIU, HSINCHU CITY (TW)

(21) Appl. No.: 18/395,728

(22) Filed: Dec. 25, 2023

(51) Int. Cl. H01L 29/66; H01L 29/08; H01L 29/10

(52) U.S. Cl. CPC H10D 10/01; H10D 62/133; H10D 62/137; H10D 62/177

(57) ABSTRACT

A semiconductor device includes an emitter, a first base encircling the emitter, a first collector encircling the emitter and the first base, a second base encircling the emitter, the first base and the first collector, and a second collector encircling the second base. The first collector is separated from the emitter by the first base, and the second collector is separated from the emitter, the first base and the first collector by the second base. The emitter, the first base, the first collector, the second base and the second collector form a concentric pattern.

### BACKGROUND

High-voltage devices are commonly used in integrated circuits (ICs), and may be used in input/output (IO) circuits, memory circuits, and the like. In addition, semiconductor circuits that include devices such as metal-oxide-semiconductor field-effect transistors (MOSFETs) are adopted for high-voltage applications. For example, high-voltage lateral diffusion metal-oxide-semiconductor (HV LDMOS) transistor devices are used in various applications. However, performance of an HV LDMOS transistor is often limited by its substrate leakage and breakdown voltage (BV) threshold. To address such issues, a high-voltage bipolar junction transistor (BJT) is provided.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view of a semiconductor device in accordance with aspects of the present disclosure in one or more embodiments.

FIG. 2 is a cross-sectional view taken along line I-I′ of FIG. 1.

FIG. 3 is a simplified top view of a semiconductor device in accordance with aspects of the present disclosure in one or more embodiments.

FIG. 4 illustrates directions of current in a semiconductor device in operation in accordance with aspects of the present disclosure in one or more embodiments.

FIG. 5 is a diagram showing a relationship between distance and electrons injected into a substrate.

FIG. 6 is a diagram showing a relationship between distance and electrons injected into a substrate.

FIG. 7 is a partially-enlarged view of a portion of a semiconductor device in accordance with aspects of the present disclosure in one or more embodiments.

FIG. 8 is a partially-enlarged view of a portion of a semiconductor device in accordance with aspects of the present disclosure in one or more embodiments.

FIG. 9 is a partially-enlarged view of a portion of a semiconductor device in accordance with aspects of the present disclosure in one or more embodiments.

FIG. 10 is a partially-enlarged view of a portion of a semiconductor device in accordance with aspects of the present disclosure in one or more embodiments.

FIG. 11 is a partially-enlarged view of a portion of a semiconductor device in accordance with aspects of the present disclosure in one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat references numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any references to direction or orientation are merely intended for convenience of description and are not intended in any way to limit the scope of the present disclosure. Relative terms such as “lower,” “upper,” “horizontal,” “vertical,” “above,” “below,” “up,” “down,” “top” and “bottom,” as well as derivatives thereof (e.g., “horizontally,” “downwardly,” “upwardly,” etc.), should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by references to the embodiments. Accordingly, the disclosure expressly should not be limited to such embodiments illustrating some possible non-limiting combination of features that may exist alone or in other combinations of features, the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

A BJT includes an emitter, a collector, and a base. The emitter and the collector can have a first doping type, and the base has a second doping type complementary to the first doping type. For example, the emitter and the collector can be of n-type, and the base is of p-type. The collector is separated from the emitter so that a high voltage can be applied between the collector and the emitter.

It is found that current may leak out of a BJT device and affect other devices nearby through a substrate where the BJT device and other devices are disposed. The influence is reduced when a distance between the BJT device and the affected device is increased. Therefore, there is a need to determine a relationship between a current at a point on the substrate and a distance between an emitter of the BJT device and that point on the substrate. In other words, a semiconductor device for characterization is needed.

The present disclosure therefore provides a semiconductor device for characterizing of an HV application. The semiconductor device is a configured to have point symmetry about an emitter, and the emitter is encircled by a plurality of ring-shaped collectors. Accordingly, currents leaked into the substrate at different locations can be easily captured, and a relationship between the current at a point on the substrate and the distance from an emitter of the BJT device and the point on the substrate can be easily characterized.

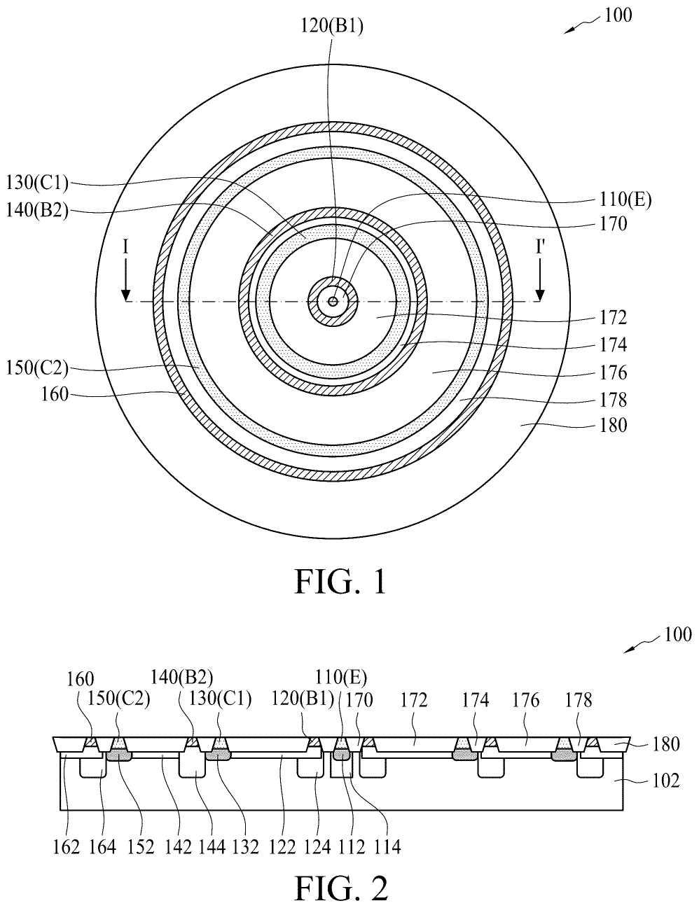

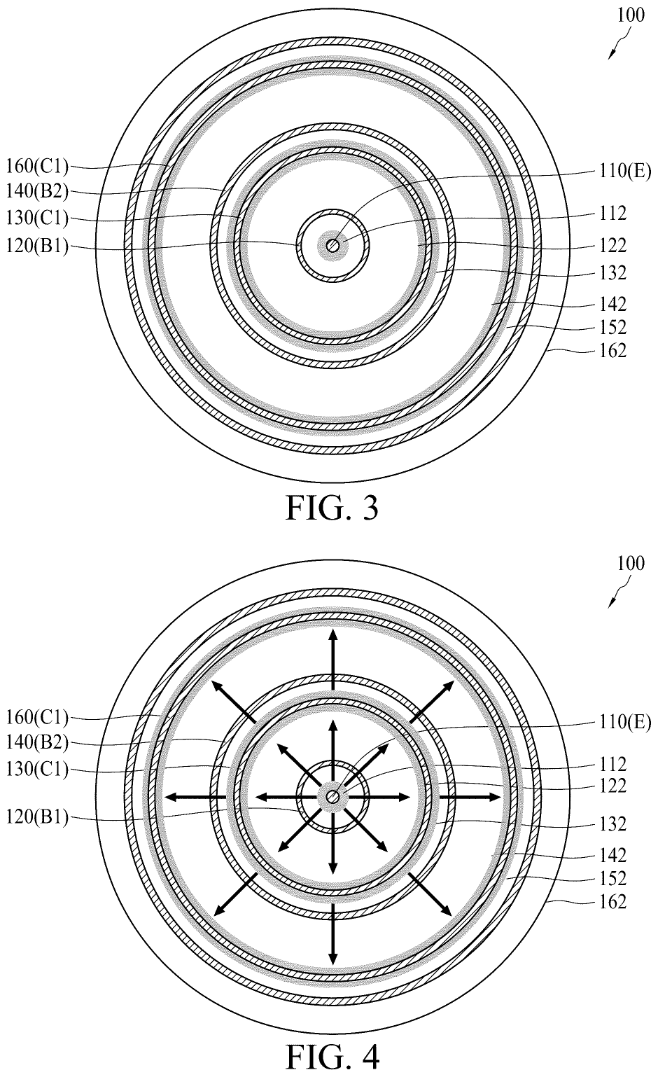

Please refer to FIGS. 1 to 3, wherein FIG. 1 is a top view of a semiconductor device in accordance with aspects of the present disclosure in one or more embodiments, FIG. 2 is a cross-sectional view taken along line I-I′ of FIG. 1, and FIG. 3 is a simplified top view of FIG. 1. In some embodiments, a semiconductor device 100 is provided. The semiconductor device 100 includes a substrate 102 (shown in FIG. 2). The substrate 102 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may be a SiGe alloy with a gradient Ge feature in which the Si/Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. Furthermore, the substrate 102 may be a semiconductor on insulator, such as silicon on insulator (SOI). In some embodiments, the substrate 102 may include a doped epitaxial layer or a buried layer. In some embodiments, the substrate 102 may have a multilayer structure, or may include a multilayer compound semiconductor structure.

The semiconductor device 100 includes a doped region 110 including dopants of a first doping type. In some embodiments, the first doping type is an n-type. In some embodiments, a doping concentration of the doped region 110 is between approximately 1E16 ion/cm³ and approximately 1E20 ion/cm³, but the disclosure is not limited thereto. In some embodiments, the doped region 110 is used as an emitter E of the semiconductor device 100.

In some embodiments, a well 112 is formed under the doped region 110. In some embodiments, a deep well 114 may be formed under the well 112. A bottom of the doped region 110 may be in contact with the well 112, and sidewalls and a bottom of the well 112 may be in contact with the deep well 114. In such embodiments, the doped region 110 and the well 112 are separated from the substrate 102 by the deep well 114. In some embodiments, sidewalls and a bottom of the deep well 114 may be in contact with the substrate 102, but the disclosure is not limited thereto. In some embodiments, the well 112 and the deep well 114 both include dopants of the first doping type. A doping concentration of the well 112 is less than the doping concentration of the doped region 110, and a doping concentration of the deep well 114 is less than the doping concentration of the well 112. In such embodiments, the doping concentrations in the doped region 110, the well 112 and the deep well 114 obtain a gradient decreasing from a top surface of the substrate 102 to a bottom of the substrate 102.

In some embodiments, the semiconductor device 100 includes a ring-shaped isolation 170 encircling the doped region 110. Further, the ring-shaped isolation 170 encircles the well 112 and the deep well 114. In some embodiments, a bottom of the ring-shaped isolation 170 may be lower than the bottom of the doped region 110. In some embodiments, the bottom of the well 112 and the bottom of the deep well 114 are lower than the bottom of the ring-shaped isolation 170. In some embodiments, a portion of the bottom of the ring-shaped isolation 170 may be in contact with the well 112. In other embodiments, a portion of the bottom of the ring-shaped isolation 170 may be in contact with the deep well 114. In still other embodiments, a portion of the ring-shaped isolation 170 may be in contact with the substrate 102.

The semiconductor device 100 further includes a doped region 120 encircling the doped region 110. The doped region 120 may further encircle the ring-shaped isolation 170. Further, the doped region 120 is separated from the doped region 110 by the ring-shaped isolation 170. The doped region 120 includes dopants of a second doping type that is complementary to the first doping type. For example, the second doping type may be a p-type. In some embodiments, a doping concentration of the doped region 120 may be between approximately 1E15 ion/cm³ and approximately 1E17 ion/cm³, but the disclosure is not limited thereto. In some embodiments, a bottom of the doped region 120 may be higher than the bottom of the ring-shaped isolation 170. In some embodiments, the doped region 120 is used as a base (B1) in the semiconductor device 100. As shown in FIGS. 1 and 2, it may be referred to as two doped regions 120 coupled to each other to form the base (B1).

The semiconductor device 100 includes a well 122 under the doped region 120. Further, the well 122 encircles the well 112, but the well 122 is separated from the well 112. In some embodiments, a depth of the well 122 may be equal to a depth of the well 112, but the disclosure is not limited thereto. As shown in FIG. 2, the bottom of the doped region 120 is in contact with the well 122. Therefore, the doped region 120 is separated from the substrate 102 by the well 122.

In some embodiments, the semiconductor device 100 further includes a deep well 124 under a portion of the well 122. In such embodiments, a portion of the bottom of the well 122 is in contact with substrate 102, and another portion of the bottom of the well 122 is in contact with the deep well 124. A bottom of the deep well 124 may be in contact with the substrate 102, but the disclosure is not limited thereto. In some embodiments, the deep well 124 encircles the deep well 114, but the deep well 124 is separated from the deep well 114, as shown in FIG. 2. The well 122 and the deep well 124 include dopants of the second doping type. A doping concentration of the well 122 is less than the doping concentration of the doped region 120, and a doping concentration of the deep well 124 is less than the doping concentration of the well 122. In such embodiments, the doping concentrations of the doped region 120, the well 122 and the deep well 124 obtain a gradient decreasing from the top surface of the substrate 102 to the bottom of the substrate 102.

The semiconductor device 100 includes a ring-shaped isolation 172 encircling the doped region 120, the ring-shaped isolation 170 and the doped region 110. Further, the ring-shaped isolation 172 covers a portion of the well 122; therefore, at least a portion of a bottom of the ring-shaped isolation 172 is in contact with the well 122. In some embodiments, the ring-shaped isolations 170 and 172 have a same depth, as shown in FIG. 2, but the disclosure is not limited thereto. In some embodiments, a width of the ring-shaped isolation 172 is greater than a width of the ring-shaped isolation 170, but the disclosure is not limited thereto.

The semiconductor device 100 includes a doped region 130 encircling the ring-shaped isolation 172, the doped region 120, the ring-shaped isolation 170, and the doped region 110. As shown in FIGS. 1 and 2, the doped region 130 is separated from the doped region 120 by the ring-shaped isolation 172. The doped region 130 includes dopants of the first doping type. In other words, the doped regions 110 and 130 include a same doping type. In some embodiments, a doping concentration of the doped region 130 is substantially equal to the doping concentration of the doped region 110. In some embodiments, the doping concentration of the doping region 130 is between approximately 1E16 ion/cm⁻³ and approximately 1E20 ion/cm⁻³, but the disclosure is not limited thereto. In some embodiments, a depth of the doped region 130 is substantially same as a depth of the doped region 120. The doped region 130 is used as a collector (C1) in the semiconductor device 100. As shown in FIGS. 1 and 2, it may be referred to as two doped regions 130 coupled to each other to form the collector (C1).

In some embodiments, the semiconductor device 100 further includes a well 132 under the doped region 130. In such embodiments, a bottom of the doped region 130 is in contact with the well 132; therefore, the doped region 130 is separated from the substrate 102 by the well 132. The well 132 include dopants of the first doping type. A doping concentration of the well 132 is less than the doping concentration of the doped region 130. In some embodiments, the doping concentration of the well 132 may be equal to the doping concentration of the well 112, and a depth of the well 132 may be substantially equal to the depth of the well 112, but the disclosure is not limited thereto.

The semiconductor device 100 includes a ring-shaped isolation 174 encircling the doped region 130, the ring-shaped isolation 172, the doped region 120, the ring-shaped isolation 170 and the doped region 110. Further, the ring-shaped isolation 174 encircles the well 132. The ring-shaped isolation 174 is separated from the ring-shaped isolation 172. In some embodiments, the ring-shaped isolations 170, 172 and 174 have a same depth, as shown in FIG. 2, but the disclosure is not limited thereto. In some embodiments, a width of the ring-shaped isolation 174 may be equal to the width of the ring-shaped isolation 172, but the disclosure is not limited thereto. In some embodiments, a bottom of the ring-shaped isolation 174 is lower than the bottom of the doped region 130, but higher than the bottom of the well 132.

The semiconductor device 100 includes a doped region 140 encircling the ring-shaped isolation 174, the doped region 130, the ring-shaped isolation 172, the doped region 120, the ring-shaped isolation 170, and the doped region 110. The doped region 140 includes dopants of the second doping type. That is, the doped regions 120 and 140 have a same doping type. A doping concentration of the doped region 140 and the doping concentration of the doped region 120 are substantially equal. In some embodiments, the doping concentration of the doped region 140 may be between approximately 1E15 ion/cm³ and approximately 1E17 ion/cm³, but the disclosure is not limited thereto. A depth of the doped region 140 and the depth of the doped region 120 may be equal, but the disclosure is not limited thereto. The doped region 140 is separated from the doped region 130 by the ring-shaped isolation 174. In some embodiments, the doped region 140 is used as a base (B2) of the semiconductor device 100. As shown in FIGS. 1 and 2, it may be referred to as two doped regions 140 coupled to each other to form the base (B2).

The semiconductor device 100 further includes a well 142 and a deep well 144. The deep well 144 encircles the wells 112, 122 and 132, and the deep well 114. The well 142 encircles the wells 112, 122 and 132, and the deep wells 114 and 144. Additionally, the well 142 is separated from the well 132 by the deep well 144. The well 142 and the deep well 144 include dopants of the second doping type. In some embodiments, a doping concentration of the well 142 is less than the doping concentration of the doped region 140, and a doping concentration of the deep well 144 is less than the doping concentration of the deep well 144. In some embodiments, the doping concentrations of the well 142 and the well 122 are equal, but the disclosure is not limited thereto. Further, a bottom of the well 142 is lower than the bottom of the doped region 140, but higher than a bottom of the deep well 142. In some embodiments, a depth of the well 142 and the depth of the deep well 122 are equal, but the disclosure is not limited thereto. In some embodiments, the doping concentrations of the deep wells 144 and 124 are equal, but the disclosure is not limited thereto. In some embodiments, the deep well 144 is disposed under the doped region 140, and the bottom of the doped region 140 is in contact with the deep well 144. In such embodiments, the doped region 140 is separated from the substrate 102 by the deep well 144. In some embodiments, a depth of the deep well 144 and the depth of the deep well 124 are equal, but the disclosure is not limited thereto.

The semiconductor device 100 includes a ring-shaped isolation 176 encircling the doped region 140, the ring-shaped isolation 174, the doped region 130, the ring-shaped isolation 172, the doped region 120, the ring-shaped isolation 170 and the doped region 110. Further, the ring-shaped isolation 176 covers the well 142. The ring-shaped isolation 176 is separated from the ring-shaped isolation 174. In some embodiments, the ring-shaped isolations 170, 172, 174 and 176 have a same depth, as shown in FIG. 2, but the disclosure is not limited thereto. In some embodiments, a width of the ring-shaped isolation 176 and the width of the ring-shaped isolation 172 are equal, but the disclosure is not limited thereto. In some embodiments, the widths of the ring-shaped isolations 172 and 176 are greater than the widths of the ring-shaped isolations 170 and 174.

The semiconductor device 100 includes a doped region 150 encircling the ring-shaped isolation 176, the doped region 140, the ring-shaped isolation 174, the doped region 130, the ring-shaped isolation 172, the doped region 140, the ring-shaped isolation 172, the doped region 120, the ring-shaped isolation 170 and the doped region 110. The doped region 150 is separated from the doped regions 110, 120, 130 and 140. As shown in FIGS. 1 and 2, the doped region 150 is separated from the doped region 140 by the ring-shaped isolation 176. The doped region 150 includes dopants of the first doping type. In other words, the doped regions 110, 130 and 150 include the same doping type. In some embodiments, a doping concentration of the doped region 150 is substantially equal to the doping concentration of the doped regions 110 and 130. In some embodiments, the doping concentration of the doped region 150 is between approximately 1E16 ion/cm³ and approximately 1E20 ion/cm³, but the disclosure is not limited thereto. In some embodiments, a depth of the doped region 150 is substantially same as the depths of the doped regions 110 and 130. Additionally, a width of the doped region 150 and a width of the doped region 130 may be equal, but the disclosure is not limited thereto. The doped region 150 is used as a collector (C2) in the semiconductor device 100. As shown in FIGS. 1 and 2, it may be referred to as two doped regions 150 coupled to each other to form the collector (C2).

In some embodiments, the semiconductor device 100 further includes a well 152 under the doped region 150. In such embodiments, a bottom of the doped region 150 is in contact with the well 152; therefore, the doped region 150 is separated from the substrate 102 by the well 152. The well 152 include dopants of the first doping type. A doping concentration of the well 152 is less than the doping concentration of the doped region 150. In some embodiments, the doping concentration of the well 152 is equal to the doping concentration of the wells 112 and 132, and a depth of the well 152 is substantially equal to the depth of the wells 112 and 132, but the disclosure is not limited thereto.

The semiconductor device 100 includes a ring-shaped isolation 178 encircling the abovementioned elements. Further, the ring-shaped isolation 178 is separated from the ring-shaped isolation 176. In some embodiments, the ring-shaped isolations 170, 172, 174, 176 and 178 have a same depth, as shown in FIG. 2, but the disclosure is not limited thereto. In some embodiments, a width of the ring-shaped isolation 178 and the widths of the ring-shaped isolations 174 and 170 are equal, but the disclosure is not limited thereto.

The semiconductor device 100 includes a doped region 160 encircling the abovementioned elements. The doped region 160 includes dopants of the second doping type. That is, the doped regions 120, 140 and 160 have the same doping type. A doping concentration of the doped region 160 and the doping concentrations of the doped regions 120 and 140 are substantially equal. In some embodiments, the doping concentration of the doped region 160 may be between approximately 1E15 ion/cm⁻³ and approximately 1E17 ion/cm⁻³, but the disclosure is not limited thereto. A depth of the doped region 160 and the depths of the doped regions 120 and 140 may be equal, but the disclosure is not limited thereto. The doped region 160 is separated from the doped region 150 by the ring-shaped isolation 178.

The semiconductor device 100 includes a well 162 under the doped region 160. In some embodiments, a depth of the well 162 may be equal to the depths of the wells 122 and 142, but the disclosure is not limited thereto. As shown in FIG. 2, a bottom of the doped region 160 is in contact with the well 162. In some embodiments, the semiconductor device 100 further includes a deep well 164 under a portion of the well 162. In such embodiments, a portion of a bottom of the well 162 is in contact with the substrate 102, and another portion of the bottom of the well 162 is in contact with the deep well 164. A bottom of the deep well 164 may be in contact with the substrate 102, but the disclosure is not limited thereto. In some embodiments, the well 162 is separated from the well 152 by the deep well 164. The well 162 and the deep well 164 include dopants of the second doping type. A doping concentration of the well 162 is less than the doping concentration of the doped region 160, and a doping concentration of the deep well 164 is less than the doping concentration of the well 162. In such embodiments, the doping concentrations of the doped region 160, the well 162 and the deep well 164 obtain a gradient decreasing from the top surface of the substrate 102 to the bottom of the substrate 102. Additionally, the doping concentration of the well 162 may be equal to the doping concentrations of the wells 122 and 142, and the doping concentration of the deep well 164 may be equal to the doping concentrations of the deep wells 124 and 144, but the disclosure is not limited thereto.

The semiconductor device 100 includes a ring-shaped isolation 180 encircling the abovementioned elements. Further, the ring-shaped isolation 180 is separated from the ring-shaped isolation 178. In some embodiments, the ring-shaped isolations 170, 172, 174, 176, 178 and 180 have a same depth, as shown in FIG. 2, but the disclosure is not limited thereto. The ring-shaped isolation 180 covers at least a portion of the well 162. In some embodiments, the ring-shaped isolation 180 may be used to electrically isolate the semiconductor device 100 from other devices. In other embodiments, the ring-shaped isolation 180 may be similar to the ring-shaped isolation 176, the doped region 160 may be used as a base (B3, not shown) in the semiconductor device 100, and elements such as the doped regions 130 and 140, the wells 132 and 142, and the deep well 144 may be repeatedly disposed to encircle the ring-shaped isolation 180.

As shown in FIGS. 1 and 3, the doped region 110 (the emitter E), the doped region 120 (the base B1), the doped region 130 (the collector C1), the doped region 140 (the base B2) and the doped region 150 (the collector C2) form a concentric pattern. In some embodiments, the doped region 160 and the abovementioned doped regions form a concentric pattern. In some embodiments, the ring-shaped isolations 170, 172, 174, 176, 178 and 180 and the abovementioned doped regions form a concentric pattern. Further, the doped region 110 (the emitter E), the doped region 120 (the base B1), the doped region 130 (the collector C1), the doped region 140 (the base B2) and the doped region 150 (the collector C2) form a point symmetric pattern about a center in the doped region 110 (the emitter E).

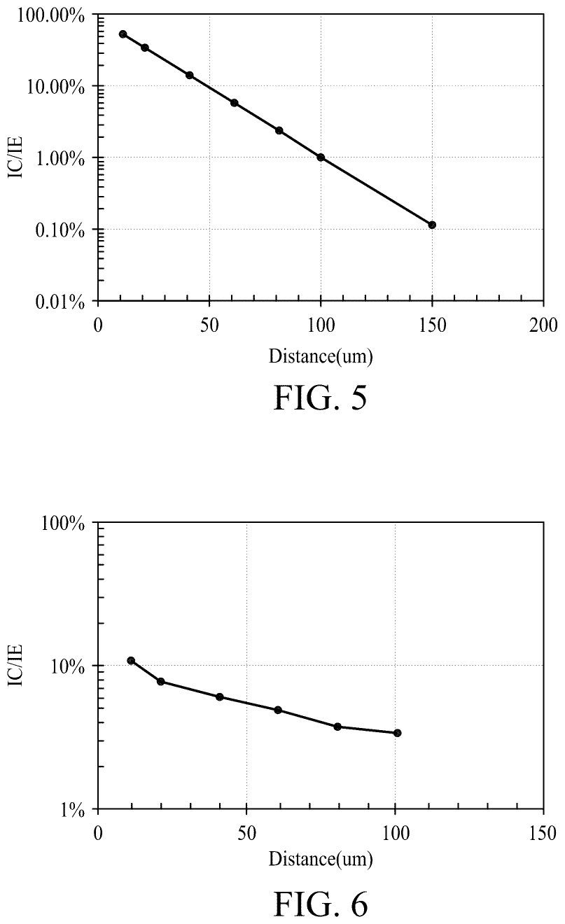

Please refer to FIG. 4, which is a schematic drawing illustrating current directions in a semiconductor device in operation. Accordingly, a distance between the emitter E and the collector B1 is equal in every direction, and a distance between the emitter E and the collector B2 is equal in every direction. Further, the semiconductor device 100 provides collectors B1 and B2 at locations that are different distances from the emitter E. As shown in FIG. 4, in some embodiments, currents from the emitter E to the collector C1 traverse same distances in every direction, while currents from the emitter E to the collector C2 traverse same distances in every direction. Further, collectors C1 and C2 are disposed at different locations that are different distances from the emitter E. Thus, a relationship between a distance from the emitter to a collector and a current at such collector can be easily modeled or characterized by the semiconductor device 100, as shown in FIGS. 5 and 6, wherein FIG. 5 is a diagram showing a relationship between the distance from the emitter to a collector and a quantity of electrons injected into the substrate at the collector, and FIG. 6 is a diagram showing a relationship between the distance from the emitter to a collector and holes injected into the substrate at such collector.

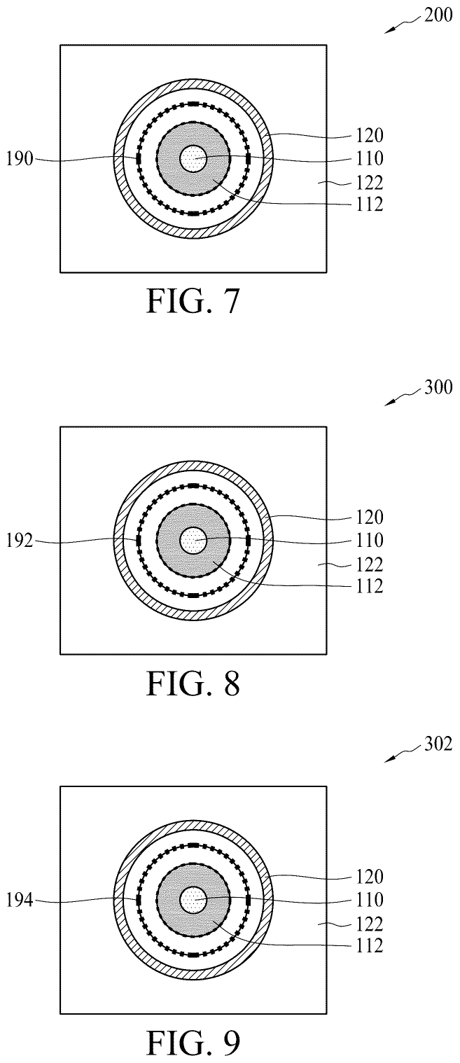

Please refer to FIGS. 7 to 9, which are enlarged views of a portion of a semiconductor device in accordance with aspects of the present disclosure in one or more embodiments. In some embodiments, a semiconductor device 200 is provided. The semiconductor device 200 may include elements that are same as those in the semiconductor device 100 (i.e., the doped regions 110 to 160, the wells 112 to 162, the deep wells 114 to 164, and the ring-shaped isolations 170 to 180); thus, similar elements are omitted from FIG. 7 and repeated descriptions of such details are omitted for brevity. As shown in FIG. 7, in some embodiments, the semiconductor device 200 further includes an undoped region 190 encircling the doped region 110. The undoped region 190 may further encircle the well 112. The undoped region 190 is disposed between the doped region 110 and the doped region 120. Further, the undoped region 190 may be disposed between the well 112 and the well 122.

In some embodiments, a semiconductor device 300 is provided. The semiconductor device 300 may include elements that are same as those in the semiconductor device 100 (i.e., the doped regions 110 to 160, the wells 112 to 162, the deep wells 114 to 164, and the ring-shaped isolations 170 to 180); thus, similar elements are omitted from FIG. 8 and repeated descriptions of such details are omitted for brevity. As shown in FIG. 8, in some embodiments, the semiconductor device 300 further includes a doped region 192 encircling the doped region 110. The doped region 192 may further encircle the well 112. The doped region 192 is disposed between the doped region 110 and the doped region 120. Further, the doped region 192 may be disposed between the well 112 and the well 122. In some embodiments, the doped region 192 and the doped region 120 include a same doping type. In some embodiments, a doping concentration of the doped region 192 may be between approximately 1E16 ion/cm³ and approximately 1E18 ion/cm³, but the disclosure is not limited thereto.

Referring to FIG. 9, in some embodiments, a semiconductor device 302 is provided. The semiconductor device 302 may include elements that are same as those in the semiconductor devices 100 and 300 (i.e., the doped regions 110 to 160, the wells 112 to 162, deep wells 114 to 164, and the ring-shaped isolations 170 to 180); thus, similar elements are omitted from FIG. 9 and repeated descriptions of such details are omitted for brevity. As shown in FIG. 9, in some embodiments, the semiconductor device 302 includes a doped region 194. In some embodiments, the doped region 194 and the doped region 110 include a same doping type. In some embodiments, a doping concentration of the doped region 194 may be between approximately 1E16 ion/cm³ and approximately 1E18 ion/cm³, but the disclosure is not limited thereto.

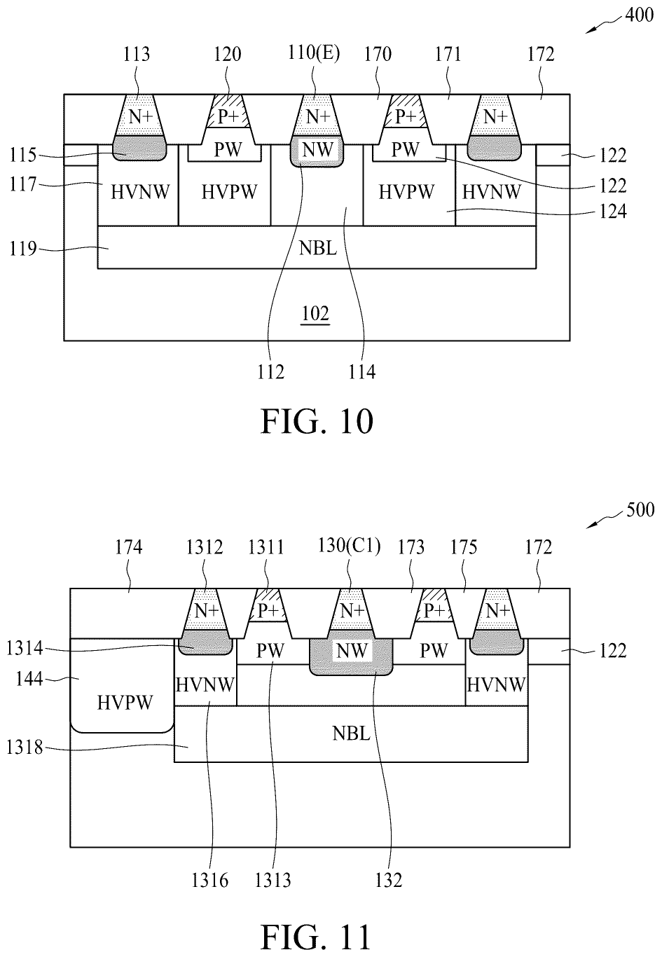

Please refer to FIG. 10, which is an enlarged view of a portion of a semiconductor device in accordance with aspects of the present disclosure in one or more embodiments. In some embodiments, a semiconductor device 400 is provided. The semiconductor device 400 may include elements that are same as those in the semiconductor device 100 (i.e., the doped regions 110 to 160, the wells 112 to 162, the deep wells 114 to 164, and the ring-shaped isolations 170 to 180); thus, similar elements are omitted from FIG. 10 and repeated descriptions of such details are omitted for brevity. In some embodiments, the semiconductor device 400 includes a doped region 113 encircling the doped regions 110 and 120. The doped region 113 and the doped region 110 include a same doping type. In some embodiments, a doping concentration of the doped region 113 is equal to the doping concentration of the doped region 110, but the disclosure is not limited thereto. Additionally, a depth of the doped region 113 and the depth of the doped region 110 may be equal, but the disclosure is not limited thereto.

In some embodiments, the semiconductor device 400 includes a well 115 disposed under the doped region 113. In some embodiments, a deep well 117 is formed under the well 115. The doped region 113, the well 115 and the deep well 117 may divide the well 122, as shown in FIG. 10. A bottom of the doped region 113 may be in contact with the well 115, and sidewalls and a bottom of the well 115 may be in contact with the deep well 117. In some embodiments, a portion of sidewalls of the deep well 117 is in contact with the substrate 102, while another portion of the sidewalls of the deep well 117 is in contact with the deep well 124, but the disclosure is not limited thereto. In some embodiments, the doped region 113 and the well 115 are separated from the substrate 102 by the deep well 117. In some embodiments, the well 115 and the deep well 117 both include dopants of the first doping type. A doping concentration of the well 115 is less than the doping concentration of the doped region 113, and a doping concentration of the deep well 117 is less than the doping concentration of the well 115. In such embodiments, the doping concentrations in the doped region 113, the well 115 and the deep well 117 obtain a gradient decreasing from the top surface of the substrate 102 to the bottom of the substrate 102. In some embodiments, the doping concentration of the well 115 may be equal to the doping concentration of the well 112, but the disclosure is not limited thereto. In some embodiments, the doping concentration of the deep well 117 may be equal to the doping concentration of the deep well 114, but the disclosure is not limited thereto.

In some embodiments, the semiconductor device 400 further includes a buried doped layer 119 disposed under the deep well 117. The buried doped layer 119 includes dopants of the first doping type. In such embodiments, the deep well 117 (which encircles the doped regions 110 and 120), the wells 112 and 122 and the deep wells 114 and 124 are coupled to each other by the buried doped layer 119, as shown in FIG. 10. In such embodiments, currents are confined in a path formed by the doped region 110 (the emitter E), the well 112, the deep well 114, the buried doped layer 119, the deep well 117, the well 115, the well 122, and the doped region 130 (the collector C1).

In such embodiments, another ring-shaped isolation 171 may be disposed between the ring-shaped isolations 170 and 172. Further, the ring-shaped isolation 171 is disposed between the doped region 120 and the doped region 113. The ring-shaped isolation 171 encircles the doped region 120, the ring-shaped isolation 170, and the doped region 110. In such embodiments, the doped region 120 and the doped region 113 are separated from each other by the ring-shaped isolation 171. In some embodiments, a depth of the ring-shaped isolation 171 may be equal to the depth of the ring-shaped isolations 170 and 172, but the disclosure is not limited thereto. In some embodiments, a width of the ring-shaped isolation 171 may be equal to the width of the ring-shaped isolation 170, but the disclosure is not limited thereto.

In some embodiments, the doped region 110, the ring-shaped isolation 170, the doped region 120, the ring-shaped isolation 171, and the doped region 113 form a line symmetric pattern about an axis in the doped region 110.

Please refer to FIG. 11, which is an enlarged view of a portion of a semiconductor device in accordance with aspects of the present disclosure in one or more embodiments. In some embodiments, a semiconductor device 500 is provided. The semiconductor device 500 may include elements that are same as those in the semiconductor device 100 (i.e., the doped regions 110 to 160, the wells 112 to 162, the deep wells 114 to 164, and the ring-shaped isolations 170 to 180); thus, similar elements are omitted from FIG. 11 and repeated descriptions of such details are omitted for brevity. In some embodiments, the semiconductor device 500 includes collectors C1 and C2, and each of the collectors C1 and C2 can include doped regions, wells and deep wells described below, although only the collector C1 is illustrated in FIG. 11.

As shown in FIG. 11, the collector C1 or C2 of the semiconductor device 500 includes a pair of doped regions 1311 and a pair of doped regions 1312. The doped region 130 is disposed between the pair of doped regions 1311, and the doped region 130 and the pair of doped regions 1311 are disposed between the pair of doped regions 1312. Further, the semiconductor device 500 includes a pair of ring-shaped isolations 173 separating each of doped regions 1311 from the doped region 130, and a pair of ring-shaped isolations 175 separating each of the doped regions 1312 from each of the pair of doped region 1311. The doped regions 1311 include dopants of the second doping type, while the doped regions 1312 include dopants of the first doping type. In some embodiments, a doping concentration of the doped region 1311 may be equal to the doping concentration of the doped region 120, but the disclosure is not limited thereto. In some embodiments, a doping concentration of the doped region 1312 may be equal to the doping concentration of the doped region 130, but the disclosure is not limited thereto.

In some embodiments, the collector C1 or C2 of the semiconductor device 500 further includes a well 1313 disposed under each of the doped regions 1311, and a well 1314 disposed under each of the doped regions 1312. The well 1313 includes dopants of the second doping type, and the well 1314 includes dopants of the first doping type. In some embodiments, a doping concentration of the well 1313 is equal to the doping concentration of the well 122, but the disclosure is not limited thereto. In some embodiments, a doping concentration of the well 1314 is equal to the doping concentration of the well 132, but the disclosure is not limited thereto.

In some embodiments, the collector C1 or C2 of the semiconductor device 500 further includes a deep well 1316 disposed under each of the wells 1314, and a buried doped layer 1318 disposed under the deep wells 1316. The deep well 1316 and the buried doped layer 1318 include dopants of the first doping type. In some embodiments, a doping concentration of each deep well 1316 is less than the doping concentration of each well 1314, and a doping concentration of the buried doped layer 1318 is less than the doping concentration of the deep well 1316. In some embodiments, the doping concentration of the deep well 1316 is equal to the doping concentration of the deep well 114, but the disclosure is not limited thereto. It should be noted that the sidewalls and a bottom of the well 1314 are in contact with the deep well 1316, and a bottom of each of the deep wells 1316 is in contact with the buried doped layer 1318. Accordingly, the pair of doped regions 1312 are electrically connected to each other through the pair of wells 1314, the pair of deep wells 1316 and the buried doped layer 1318.

As shown in FIG. 11, in some embodiments, the doped region 130, the well 132, the pair of ring-shaped isolations 173, the pair of doped regions 1311, the pair of wells 1313, the pair of ring-shaped isolations 175, the pair of doped region 1312, the pair of wells 1314, the pair of deep wells 1316, and the buried doped layer 1318 are disposed between the ring-shaped isolation 172 and the ring-shaped isolation 174.

In some embodiments, the doped region 130, the pair of ring-shaped isolations 173, the pair of doped regions 1311, the pair of ring-shaped isolations 175 and the pair of doped regions 1312 form a line symmetric pattern about an axis in the doped region 130. In some embodiments, the doped region 130, the well 132, the ring-shaped isolation 173, the pair of doped regions 1311, the pair of wells 1313, the pair of ring-shaped isolations 175, the pair of doped regions 1312, the pair of wells 1314, the pair of deep wells 1316 and the buried doped layer 1318 form a line symmetric pattern about an axis in the doped region 130 and the well 132.

Accordingly, the present disclosure provides a semiconductor device for modeling or charactering of an HV application. The semiconductor device is configured to have a point symmetry about an emitter, and the emitter is encircled by a plurality of ring-shaped collectors. Accordingly, currents injected into the substrate at different locations can be easily captured, and a relationship between the current at a point on the substrate and a distance between the BJT device and the point on the substrate can be easily modeled or characterized.

In accordance with one embodiment of the present disclosure, a semiconductor device is provided. The semiconductor device includes an emitter, a first base encircling the emitter, a first collector encircling the emitter and the first base, a second base encircling the emitter, the first base and the first collector, and a second collector encircling the second base. The first collector is separated from the emitter by the first base, and the second collector is separated from the emitter, the first base and the first collector by the second base. The emitter, the first base, the first collector, the second base and the second collector form a concentric pattern.

In accordance with one embodiment of the present disclosure, a semiconductor device is provided. The semiconductor device includes a first doped region, a second doped region encircling the first doped region, a third doped region encircling the first doped region and the second doped region, a fourth doped region encircling the first doped region, the second doped region and the third doped region, and a fifth doped region encircling the first doped region, the second doped region, the third doped region and the fourth doped region. The third doped region is separated from the first doped region by the second doped region. The first doped region, the third doped region and the fifth doped region have a first doping type, and the second doped region and the fourth doped region have a second doping type complementary to the first doping type.

In accordance with one embodiment of the present disclosure, a semiconductor device is provided. The semiconductor device includes a first collector and a second collector separated from each other, a third collector and a fourth collector disposed between the first collector and the second collector and an emitter disposed between and separated from the third collector and the fourth collector. The first collector and the second collector are coupled to each other, and the third collector and the fourth collector are coupled to each other. The third collector and the fourth collector are separated from the first collector and the second collector. A distance between the first collector and the emitter is equal to a distance between the second collector and the emitter, and a distance between the third collector and the emitter is equal to a distance between the fourth collector and the emitter.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
an emitter;
a first base encircling the emitter;
a first collector encircling the emitter and the first base, wherein the first collector is separated from the emitter by the first base;
a second base encircling the emitter, the first base and the first collector; and
a second collector encircling the second base, and separated from the emitter, the first base and the first collector by the second base,
wherein the emitter, the first base, the first collector, the second base and second collector form a concentric pattern.

2. The semiconductor device of claim 1, wherein the emitter, the first base, the first collector, the second base and the second collector form a point symmetric pattern about a center in the emitter.

3. The semiconductor device of claim 1, further comprising an undoped region encircling the emitter, wherein the undoped region is disposed between the emitter and the first base.

4. The semiconductor device of claim 1, further comprising a doped region encircling the emitter, wherein the doped region is disposed between the emitter and the first base.

5. The semiconductor device of claim 4, wherein the doped region and the emitter comprise a same doping type.

6. The semiconductor device of claim 4, wherein the doped region and the first base comprise a same doping type.

7. The semiconductor device of claim 1, further comprising:
a first ring-shaped isolation encircling the emitter and separating the first base from the emitter;
a second ring-shaped isolation encircling the first ring-shaped isolation and covering a portion of the first base;
a third ring-shaped isolation encircling the first ring-shaped isolation, the second ring-shaped isolation and the first collector;
a fourth ring-shaped isolation encircling the first ring-shaped isolation, the second ring-shaped isolation and the third ring-shaped isolation, and covering a portion of the second base; and
a fifth ring-shaped isolation encircling the first ring-shaped isolation, the second ring-shaped isolation, the third ring-shaped isolation, the fourth ring-shaped isolation, and the second collector.

8. A semiconductor device comprising:
a first doped region;
a second doped region encircling the first doped region;
a third doped region encircling the first doped region and the second doped region, and separated from the first doped region by the second doped region;
a fourth doped region encircling the first doped region, the second doped region and the third doped region; and
a fifth doped region encircling the first doped region, the second doped region, the third doped region and the fourth doped region,
wherein the first doped region, the third doped region and the fifth doped region have a first doping type, and the second doped region and the fourth doped region have a second doping type complementary to the first doping type.

9. The semiconductor device of claim 8, wherein a doping concentration of the first doped region, a doping concentration of the third doped region and a doping concentration of the fifth doped region are substantially equal.

10. The semiconductor device of claim 8, wherein a doping concentration of the second doped region and a doping concentration of the fourth doped region are substantially equal.

11. The semiconductor device of claim 8, further comprising:
a first well under the first doped region;
a second well encircling and separated from the first well;
a third well under the third doped region;
a fourth well encircling the first well, the second well and the third well; and
a fifth well under the fifth doped region,
wherein the first well, the third well and the fifth well have the first doping type, and the second well and the fourth well have the second doping type.

12. The semiconductor device of claim 11, further comprising:
a first ring-shaped isolation encircling the first doped region and the first well;
a second ring-shaped isolation encircling the second doped region and covering a portion of the second well;
a third ring-shaped isolation encircling the first ring-shaped isolation, the second ring-shaped isolation, the third doped region and the third well;
a fourth ring-shaped isolation encircling the first ring-shaped isolation, the second ring-shaped isolation, and the third ring-shaped isolation, and covering the fourth well; and
a fifth ring-shaped isolation encircling the first ring-shaped isolation, the second ring-shaped isolation, the third ring-shaped isolation, the fourth ring-shaped isolation, the fifth doped region, and the fifth well.

13. The semiconductor device of claim 11, further comprising:
a first deep well under the first well;
a second deep well under a portion of the second well; and
a third deep well under the fourth doped region,
wherein the first deep well has the first doping type, and the second deep well and the third deep well have the second doping type.

14. The semiconductor device of claim 11, further comprising:
a sixth doped region encircling the first doped region and the second doped region;
a sixth well under the sixth doped region;
a first deep well under the first well;
a second deep well under the second well;
a third deep well under the sixth well; and
a buried layer under the first deep well, the second deep well and the third deep well,
wherein the sixth doped region, the first deep well, the third deep well and the buried layer have the first doping type, and the second deep well has the second doping type.

15. A semiconductor device comprising:
a first collector and a second collector separated from each other;
a third collector and a fourth collected disposed between the first collector and the second collector, and separated from each other; and
an emitter disposed between and separated from the third collector and the fourth collector;
wherein the first collector and the second collector are coupled to each other, and the third collector and the fourth collector are coupled to each other, and
wherein a distance between the first collector and the emitter is equal to a distance between the second collector and the emitter, and a distance between the third collector and the emitter is equal to a distance between the fourth collector and the emitter.

16. The semiconductor device of claim 15, wherein the first collector, the second collector, the third collector, the fourth collector and the emitter comprise a same doping type.

17. The semiconductor device of claim 15, further comprising
a first base between the first collector and the third collector;
a second base between the third collector and the emitter;
a third base between the emitter and the fourth collector; and
a fourth base between the fourth collector and the second collector.

18. The semiconductor device of claim 17, further comprising a first doped region and a second doped region, wherein the emitter, the second base and the third base are disposed between the first doped region and the second doped region.

19. The semiconductor device of claim 18, further comprising a first deep well under the first doped region, a second deep well under the second doped region, and a buried layer under the first deep well and the second deep well, wherein the first doped region and the second doped region are coupled to each other through the first deep well, the buried layer and the second deep well.

20. The semiconductor device of claim 15, wherein each of the third collector and the fourth collector further comprises:
a first doped region having a first doping type;
a pair of second doped regions having a second doping type complementary to the first doping type;
a pair of third doped regions having the first doping type;
a pair of deep wells under the pair of the third doped regions; and
a buried layer coupled to the pair of deep wells,
wherein the first doped region is disposed between the pair of second doped regions, and the first doped region and the pair of second doped regions are disposed between the pair of third doped regions.
